(19) United States
(12) Patent Application Publication
(10) Pub. No.: US 2021/0068287 A1
(43) Pub. Date: Mar. 4, 2021

(54) ELECTRIC CONNECTION BOX

(71) Applicants: YAZAKI CORPORATION, Tokyo (JP); HONDA MOTOR CO., LTD., Tokyo (JP)

(72) Inventors: Hideaki Kanemitsu, Makinohara-shi (JP); Takashi Sugiyama, Makinohara-shi (JP); Tsukasa Saito, Makinohara-shi (JP); Yuya Tokuda, Makinohara-shi (JP); Toshihisa Yagi, Tokyo (JP); Masayuki Sunamoto, Wako-shi (JP); Gota Masuda, Asaka-shi (JP)

(21) Appl. No.: 16/938,904

(22) Filed: Jul. 24, 2020

(30) Foreign Application Priority Data
Aug. 26, 2019 (JP) 2019-153847

(51) Int. Cl. H05K 7/10; H02B 1/48; H02B 1/20

(52) U.S. Cl. CPC H05K 7/1053; H02B 1/20; H02B 1/48

(57) ABSTRACT

An electric connection box includes a base having a relay mounting portion on which a relay is configured to be mounted. The base has a component mounting portion on which a component is configured to be mounted at a lower position of the relay mounted on the relay mounting portion. The component mounting portion is disposed so that at least a part of the component mounting portion overlaps with an area of the base in which the relay is mounted in a plan view.

### CROSS REFERENCE TO RELATED APPLICATIONS

This application claims priority from Japanese Patent Application No. 2019-153847 filed on Aug. 26, 2019, the entire contents of which are incorporated herein by reference.

### BACKGROUND OF THE INVENTION

### Field of the Invention

The present invention relates to an electric connection box.

### Description of Related Art

An electric connection box such as a junction box or a fuse box mounted on a vehicle such as an automobile includes a base on which electronic components such as a relay and a fuse are mounted (see, for example. Patent Literature 1: JP-A-2015-204717 and Patent Literature 2: JP-A-2018-7424).

### [Patent Literature 1] JP-A-2015-204717

### [Patent Literature 2] JP-A-2018-7424

In the electric connection box, the number of electronic components mounted on the base may increase depending on a vehicle type, a grade of a vehicle, or the like. When the number of electronic components mounted on the base increases, the size of the base is increased in order to ensure a mounting space, which leads to an increase in the overall size.

### SUMMARY

One or more embodiments provide an electric connection box capable of mounting components with a high density while suppressing an increase in a size.

In an aspect (1), an electric connection box includes a base having a relay mounting portion on which a relay is configured to be mounted. The base has a component mounting portion on which a component is configured to be mounted at a lower position of the relay mounted on the relay mounting portion. The component mounting portion is disposed so that at least a part of the component mounting portion overlaps with an area of the base in which the relay is mounted in a plan view.

According to the aspect (1), the component mounting portion is disposed so that at least a part of the component mounting portion overlaps with an area of the base in which the relay is mounted in a plan view. Therefore, the components can be mounted at a high density without increasing the size of an outer shape of the base.

In an aspect (2), the component may be a joined portion in which end portions of a plurality of electric wires are collectively joined. The component may be configured to be accommodated in the component mounting portion.

According to the aspect (2), since the joined portion in which the end portions of the plurality of electric wires are collectively jointed is accommodated in the component mounting portion, for example, signals can be easily branched or the like.

In an aspect (3), the plurality of electric wires may be collectively connected to a joint terminal. The joint terminal may be configured to be accommodated in the component mounting portion.

According to the aspect (3), the plurality of electric wires can be conducted by the joint terminal accommodated in the component mounting portion.

In an aspect (4), a diode may be accommodated in and mounted to the component mounting portion.

According to the aspect (4), the diode can be accommodated in and mounted to the component mounting portion to achieve high functionality.

According to one or more embodiments, it is possible to provide the electric connection box capable of mounting components at a high density while suppressing an increase in a size.

The present invention has been briefly described above. Details of the present invention will be further clarified by reading through an embodiment for carrying out the invention to be described below with reference to the accompanying drawings.

### BRIEF DESCRIPTION OF THE DRAWINGS

FIG. 1 is a perspective view of a base, a lower cover, and an upper cover forming an electric connection box according to an embodiment.

FIG. 2 is a perspective view of the base.

FIG. 3 is a plan view of the base.

FIG. 4 is a sectional view taken along a line A-A in FIG. 3.

FIG. 5 is a sectional view taken along a line B-B in FIG. 3.

FIG. 6 is a perspective view of a relay mounting portion and a component mounting portion in the base.

FIG. 7 is a side view of a part of the base.

FIG. 8 is a perspective view of the relay mounting portion and the component mounting portion in the base.

FIG. 9 is a perspective view of a relay mounting portion and a component mounting portion in a base for explaining a modification.

FIG. 10 is a sectional view taken along a line C-C in FIG. 9.

### DETAILED DESCRIPTION

Hereinafter, embodiments of the present invention will be described with reference to the drawings.

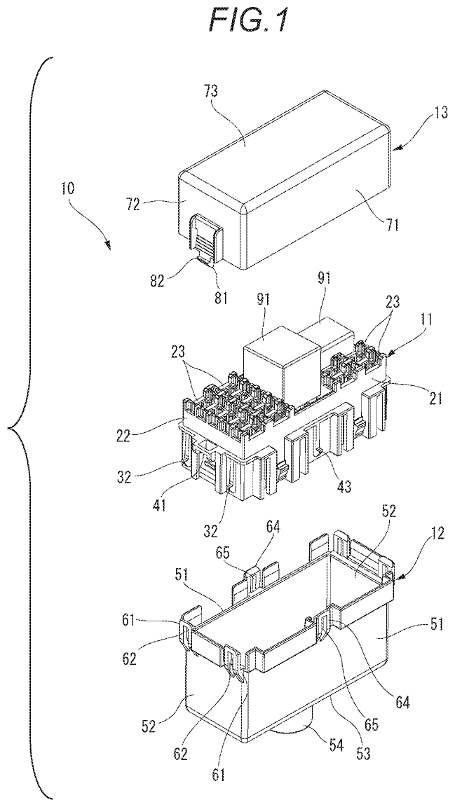

FIG. 1 is a perspective view of a base, a lower cover, and an upper cover forming an electric connection box according to an embodiment.

As shown in FIG. 1, an electric connection box 10 according to the present embodiment includes a base 11, a lower cover 12, and an upper cover 13. The electric connection box 10 is mounted on a vehicle such as an automobile, for example, and accommodates various electronic components such as a relay, a fuse, a connector, and a terminal.

The base 11, the lower cover 12, and the upper cover 13 are integrally molded from an insulating synthetic resin, respectively. The lower cover 12 is assembled to a lower portion of the base 11, and the upper cover 13 is assembled to an upper portion of the base 11.

The base 11 is formed in a rectangular shape in a plan view including a pair of side surface portions 21 and a pair of end surface portions 22. The base 11 includes, at the upper portion thereof, a plurality of mounting portions 23 on which electronic components such as a fuse and a relay can be mounted. In addition, a terminal is mounted to the mounting portion 23 from a lower side of the base 11. Further, an electric wire (not shown) connected to the terminal is led out from the lower side of the base 11.

A plurality of lower cover locking claws 32 are formed on each of the end surface portions 22 of the base 11. In addition, the end surface portion 22 is provided with an upper cover locking portion 41 between the lower cover locking claws 32. The upper cover locking portion 41 is formed in a frame shape and is provided near an upper end of the end surface portion 22. In addition, each of the side surface portions 21 of the base 11 is provided with a lower cover locking claw 43 at a center position in a width direction.

The lower cover 12 is assembled to the base 11 from the lower side thereof. As a result, the lower side of the base 11 from which the electric wire is led out is covered with the lower cover 12. The lower cover 12 includes a pair of side plate portions 51, a pair of end plate portions 52, and a bottom plate portion 53, and is formed in a box shape with an open upper side. A tubular electric wire lead-out portion 54 is formed on the bottom plate portion 53, and the electric wires led out from the lower side of the base 11 are bundled and led out to the electric wire lead-out portion 54.

The lower cover 12 includes a pair of locking portions 61 at an upper edge portion of each of the end plate portions 52. The locking portions 61 are each formed in a frame shape having a locking hole 62, and are arranged at intervals in a width direction at the upper edge portion of the end plate portion 52. In addition, each of the side plate portions 51 of the lower cover 12 is provided with a locking portion 64 at a center position in a width direction. The locking portion 64 is formed in a frame shape having a locking hole 65.

When the lower cover 12 is assembled to the base 11 from the lower side thereof, the lower portion of the base 11 is fitted into the lower cover 12. Then, the lower cover locking claw 32 of the base 11 is inserted into and locked to the locking hole 62 of the locking portion 61 of the lower cover 12 The lower cover locking claw 43 of the base 11 is inserted into and locked to the locking hole 65 of the locking portion 64 of the lower cover 12. As a result, the lower cover 12 is maintained in an assembled state with respect to the base 11.

The upper cover 13 is assembled to the base 11 from the upper side thereof. As a result, the upper side of the base 11 including the mounting portion 23 on which electronic components are mounted is covered with the upper cover 13. The upper cover 13 includes a pair of side plate portions 71, a pair of end plate portions 72, and an upper plate portion 73, and is formed in a box shape with an open lower side.

The upper cover 13 includes locking pieces 81 protruding from lower edge portions of the respective end plate portions 72 in an assembling direction to the base 11 at center positions of the respective end plate portions 72 in a width direction. A locking claw 82 protruding outward is formed in each of the locking pieces 81.

When the upper cover 13 is assembled to the base 11 from the upper side thereof, the upper portion of the base 11 is fitted into the upper cover 13. Then, the locking claw 82 formed on the locking piece 81 of the upper cover 13 locks the upper cover locking portion 41. As a result, the upper cover 13 is maintained in an assembled state with respect to the base 11.

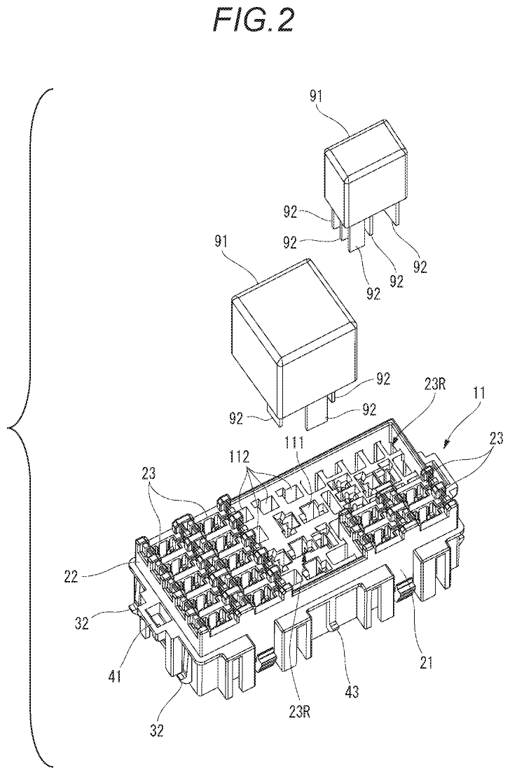

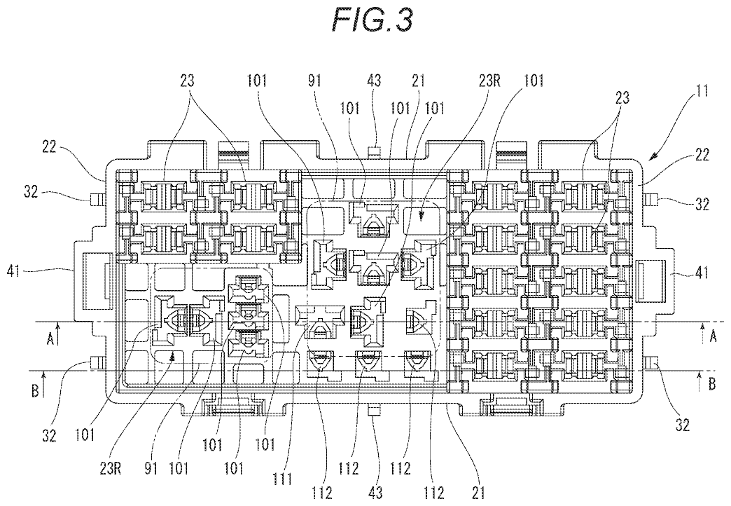

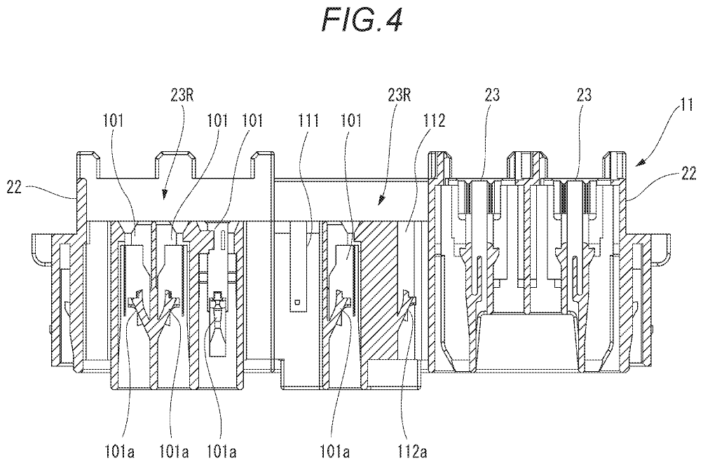

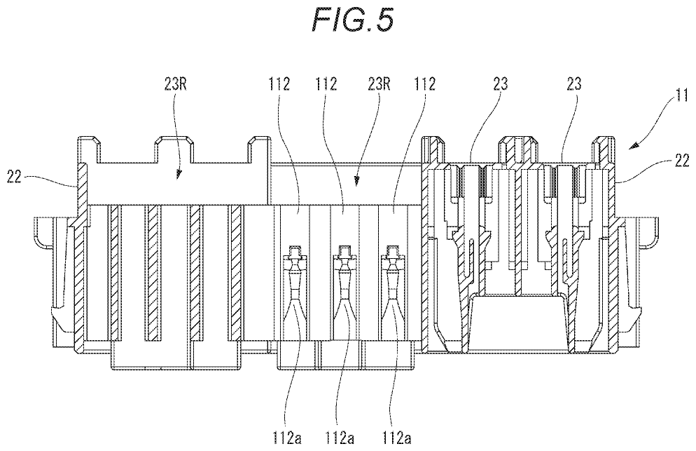

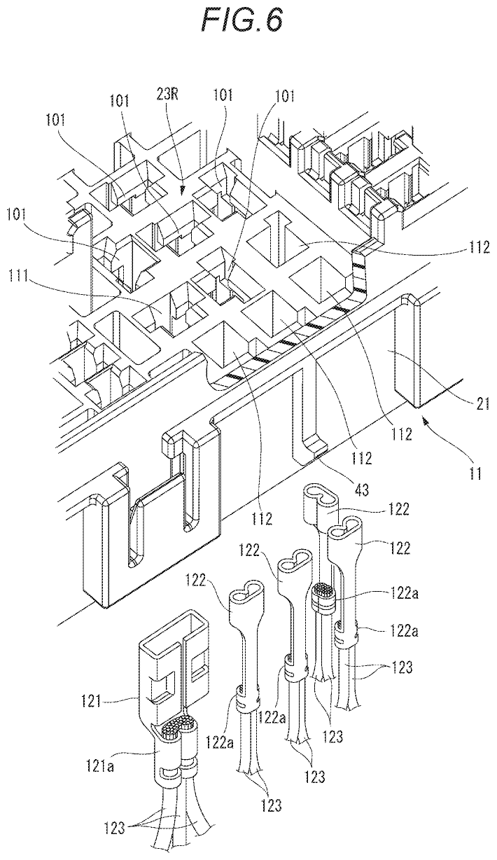

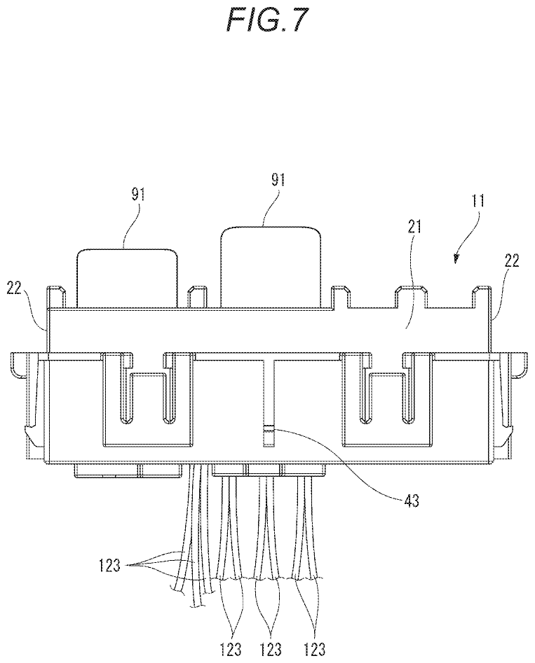

FIG. 2 is a perspective view of the base. FIG. 3 is a plan view of the base. FIG. 4 is a sectional view taken along a line A-A in FIG. 3. FIG. 5 is a sectional view taken along a line B-B in FIG. 3. FIG. 6 is a perspective view of a relay mounting portion and a component mounting portion in the base. FIG. 7 is a side view of a part of the base.

As shown in FIGS. 2 and 3, a part of the mounting portion 23 of the base 11 is relay mounting portions 23R. Each of the relay mounting portions 23R is a mounting portion on which a relay 91, which is a large electronic component, is mounted. The relay 91 mounted on the relay mounting portion 23R is formed in a rectangular parallelepiped shape, and a plurality of leg portions 92 are provided on a lower portion thereof. The relay mounting portion 23R on which the relay 91 is mounted includes a plurality of connection portions 101 into which the leg portions 92 are inserted.

As shown in FIG. 4, each of the connection portions 101 provided in the relay mounting portion 23R of the base 11 is formed of a hole portion, and a terminal (not shown) connected to an end portion of the electric wire is inserted from the lower side and accommodated therein. The leg portion 92 of the relay 91 is inserted into the connection portion 101 provided with the terminal. Accordingly, the leg portion 92 of the relay 91 is electrically connected to the terminal of the connection portion 101. Incidentally, a lance 101a is formed on an inner surface of the connection portion 101, and the terminal inserted into the connection portion 101 is locked by the lance 101a.

As shown in FIGS. 3 to 5, one relay mounting portion 23R is provided with a plurality of component mounting portions 111, 112. The component mounting portions 111, 112 are arranged below the relay 91 mounted on the relay mounting portion 23R, respectively. At least a part of the component mounting portions 111, 112 is provided at a position overlapping with an area an area of the base 11 in which the relay 91 is mounted (an area indicated by a two-dot chain line in FIG. 3) in a plan view. The component mounting portions 111, 112 are each configured by a hole portion with an open lower side. Incidentally, the (one) component mounting portion 111 has an inner shape larger than that of the (other) component mounting portion 112.

As shown in FIG. 6, joint terminals 121, 122 are accommodated in the component mounting portion 111, 112, respectively. These joint terminals 121, 122 include crimping portions 121a, 122a, and a plurality of electric wires 123 are collectively crimped and connected to the crimping portions 121a, 122a, respectively. As a result, the plurality of electric wires 123 connected to the joint terminals 121, 122 are electrically connected to each other. Incidentally, the (one) joint terminal 121 has a larger outer shape than the (other) joint terminal 122.

The joint terminals 121, 122 are inserted into the component mounting portions 111, 112 from the lower side. Lances (a lance of the component mounting portion 111 is not shown, and a lance 112a is formed on the component mounting portion 112) are respectively formed on the inner surfaces of the component mounting portions 111, 112 (see FIGS. 4 and 5). Accordingly, the joint terminals 121, 122 inserted into the component mounting portions 111, 112 are locked by the lance of the component mounting portion 111 and the lance 112a of the component mounting portion 112, and are maintained in a state of being accommodated in the component mounting portions 111, 112. As shown in FIG. 7, the electric wires 123 connected to the joint terminals 121, 122 are led out to the lower side of the base 11.

As described above, according to the electric connection box 10 according to the present embodiment, the component mounting portions 111, 112 on which components different from the relay 91 are mounted are provided on the base 11 at a lower position where at least a part thereof overlaps with the area an area of the base 11 in which the relay 91 is mounted in a plan view. Therefore, the components can be mounted at a high density without increasing the size of an outer shape of the base 11.

Specifically, the component mounting portions 111, 112 accommodates the joint terminals 121, 122 in which end portions of the plurality of electric wires 123 are collectively joined. As a result, for example, the plurality of electric wires 123 such as signal lines can be joined to easily branch signals.

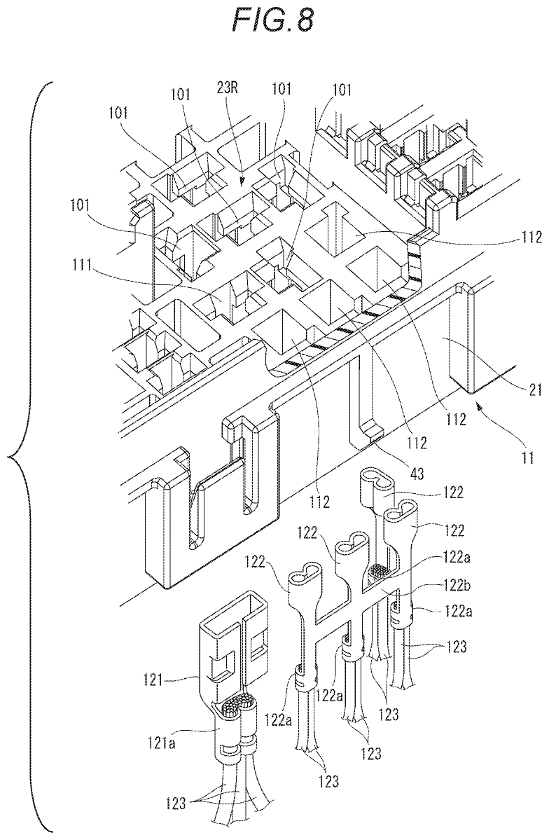

As shown in FIG. 8, the plurality of joint terminals 122 may be connected to each other by a connection portion 122b. As described above, by using the plurality of joint terminals 122 connected by the connection portion 122b, the plurality of electric wires 123 connected to the joint terminals 122 can be conducted collectively.

A joint bus bar may be inserted from above with respect to the joint terminals 121, 122 accommodated in the component mounting portions 111, 112, and the joint terminals 121, 122 may be connected to each other by the joint bus bar so as to be conducted.

Further, a joint bus bar may be inserted from above with respect to a plurality of wire harness terminals accommodated in the component mounting portions 111, 112, and the plurality of wire harness terminals may be connected to each other by the joint bus bar so as to be conducted.

Next, a modification will be described.

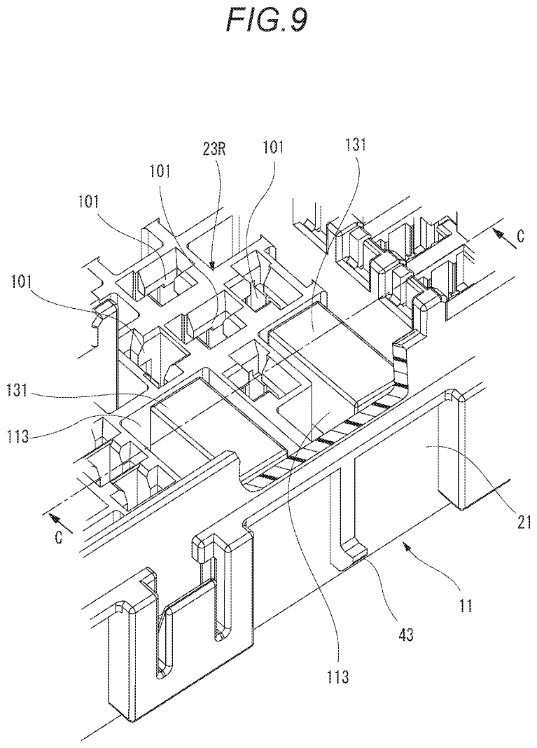

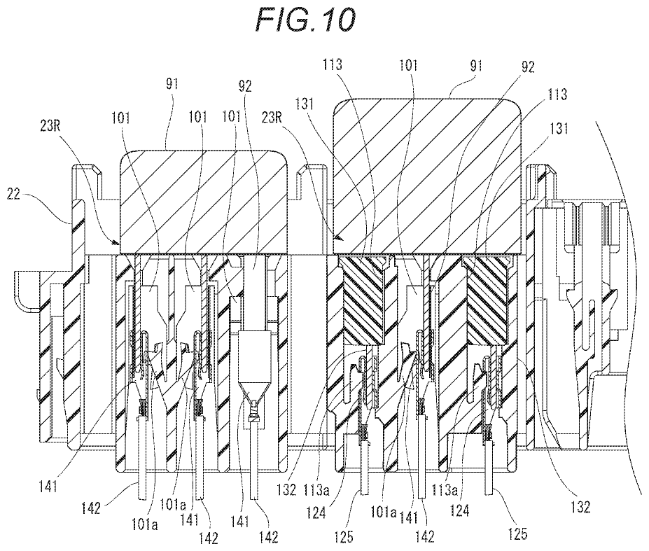

FIG. 9 is a perspective view of a relay mounting portion and a component mounting portion in a base for explaining the modification. FIG. 10 is a sectional view taken along a line C-C in FIG. 9.

As shown in FIGS. 9 and 10, in the modification, the relay mounting portion 23R is provided with component mounting portions 113 capable of accommodating diodes 131. A terminal 124 connected to an electric wire 125 is inserted from a lower side and accommodated in a lower portion of each of the component mounting portions 113. A lance 113a is formed on an inner surface of each of the component mounting portions 113, and the terminal 124 is locked to the lance 113a.

The diode 131 is inserted from an upper side into the component mounting portion 113 and accommodated therein, and a leg portion 132 thereof is inserted into and electrically connected to the terminal 124. An upper surface of the diode 131 accommodated in the component mounting portion 113 is arranged below an upper surface of the relay mounting portion 23R of the base 11. As a result, when the relay 91 is mounted on the relay mounting portion 23R, the relay 91 is prevented from interfering with the diode 131.

As described above, in the modification, the diode 131 can be accommodated and assembled in the component mounting portion 113 provided below the relay mounting portion 23R while suppressing the increase in the size of the base 11, and high functionality can be achieved.

In the connection portion 101 of the relay mounting portion 23R, terminals 141 connected to electric wires 142 are locked and accommodated by the respective lances 101a, and the leg portion 92 of the relay 91 mounted on the relay mounting portion 23R is inserted into and electrically connected to the terminal 141.

The present invention is not limited to the embodiment described above, and modifications, improvements, or the like can be made as appropriate. In addition, the material, shape, size, number, arrangement position, or the like of each component in the embodiment described above are optional and are not limited as long as the present invention can be achieved.

For example, in the above embodiment, a case where the joint terminals 121, 122 and the diode 131 are accommodated in the component mounting portions 111, 112, and 113 is illustrated, but the electronic components to be accommodated in the component mounting portions 111, 112, and 113 are not limited to the joint terminals 121, 122 and the diode 131. For example, conductors of the electric wires may be joined by a bonder process or an ultrasonic process, and the joined portion may be inserted into the component mounting portion and accommodated therein.

Here, characteristics of the embodiment of the electric connection box according to the present invention described above are summarized briefly in the following [1] to [4], respectively.

[1] An electric connection box (10) comprising:

a base (H) having a relay mounting portion (23R) on which a relay (91) is configured to be mounted,

wherein the base (11) has a component mounting portion (111, 112) on which a component (the joint terminals 121, 122, the joint bus bar) is configured to be mounted at a lower position of the relay (91) mounted on the relay mounting portion (23R), and

wherein the component mounting portion (111, 112) is disposed so that at least a part of the component mounting portion (111, 112) overlaps with an area of the base (11) in which the relay (91) is mounted in a plan view.

[2] The electric connection box according to [1],

wherein the component (joint terminals 121, 122) is a joined portion in which end portions of a plurality of electric wires (123) are collectively joined, and

wherein the component is configured to be accommodated in the component mounting portion (111, 112).

[3] The electric connection box according to [2],

wherein the plurality of electric wires (123) are collectively connected to a joint terminal (121, 122), and

wherein the joint terminal (121, 122) is configured to be accommodated in the component mounting portion (111, 112).

[4] The electric connection box according to [1],

wherein a diode (131) is accommodated in and mounted to the component mounting portion (113).

### DESCRIPTION OF REFERENCE NUMERALS AND SIGNS

10 electric connection box
11 base
23R relay mounting portion
91 relay
111, 112, 113 component mounting portion
121, 122 joint terminal (component)
123 electric wire
131 diode (component)

What is claimed is:

1. An electric connection box comprising:
a base having a relay mounting portion on which a relay is configured to be mounted,
wherein the base has a component mounting portion on which a component is configured to be mounted at a lower position of the relay mounted on the relay mounting portion, and
wherein the component mounting portion is disposed so that at least a part of the component mounting portion overlaps with an area of the base in which the relay is mounted in a plan view.

2. The electric connection box according to claim 1,
wherein the component is a joined portion in which end portions of a plurality of electric wires are collectively joined, and
wherein the component is configured to be accommodated in the component mounting portion.

3. The electric connection box according to claim 2,
wherein the plurality of electric wires are collectively connected to a joint terminal, and
wherein the joint terminal is configured to be accommodated in the component mounting portion.

4. The electric connection box according to claim 1,
wherein a diode is accommodated in and mounted to the component mounting portion.
